(19) United States
(12) Patent Application Publication
(10) Pub. No.: US 2013/0192517 A1
(43) Pub. Date: Aug. 1, 2013

(54) Method And System For Alumina Nanofibers Synthesis From Molten Aluminum

(71) Applicant: ANF Technology Limited, Warlingham (GB)

(72) Inventor: Mihhail Kutuzov, Tallinn (EE)

(73) Assignee: ANF TECHNOLOGY LIMITED, Warlingham (GB)

(21) Appl. No.: 13/756,366

(22) Filed: Jan. 31, 2013

Related U.S. Application Data
(60) Provisional application No. 61/593,204, filed on Jan. 31, 2012.

(51) Int. Cl. C30B 9/00

(52) U.S. Cl. CPC C30B 9/00; Y10S 977/762; B82Y 30/00
USPC 117/75; 117/206; 977/762

(57) ABSTRACT

A method for synthesizing monocrystalline alumina nanofibers by controlled liquid phase oxidation of a melt including molten aluminum. The method comprises two stages. During the first stage, metallic aluminum is melted and various additives are introduced into the melt. During the second stage, the alumina nanofibers are synthesized from the resulting melt in the presence of oxygen. In one or more embodiments, the inventive method is performed in a reactor. The reactor is designed to provide the heating and to enable melting of metallic aluminum. In addition, the reactor is designed to maintain a sustained temperature of between 660° C. and 1,000° C. When the additives are introduced into the molten aluminum, it is desirable to provide steady and uniform the stirring of the melt. To this end, the reactor may be provided with a stirring mechanism.

### CROSS-REFERENCE TO RELATED APPLICATION

This regular U.S. patent application relies on and claims the benefit of priority to U.S. provisional patent application No. 61/593,204 filed on Jan. 31, 2012, the entire disclosure of which is incorporated by reference herein.

### BACKGROUND OF THE INVENTION

1. Field of the Invention

This invention relates in general to nano technology and, more specifically, to technology for synthesizing alumina Al₂O₃ nanofibers from molten aluminum.

2. Description of the Related Art

Nanotechnology deals with developing materials, devices, or other structures having at least one dimension sized between 1 and 100 nanometers. Nanoparticles are the particles having at least one dimension sized between 1 and 100 nanometers. On the other hand, nanofibers are defined as fibers with diameters less than 1000 nanometers.

At the present time, several kinds of nanoparticles are known in the art, including, without limitation, carbon nano tubes (CNT), nano powders produced from silicon carbide, alumina and other materials. Also known in the art are various methods for nanoparticle or nanofiber fabrication, including, without limitation: hydrothermal process, sol gel process, mercury mediated process, flame-spray method, vapor-liquid-solid process as well as electrospinning method.

However, the conventional methods for nanoparticle fabrication suffer from low production output and, consequently, are expensive and time consuming. For example, a system for enabling a typical electrospinning nanofiber fabrication process consists of three major components: a high-voltage power supply, a spinneret, and an electrically conductive collector. A liquid used in the aforesaid electrospinning technique is fed at a predetermined rate using a syringe or other suitable pump. In many cases, a well-controlled environment (e.g., humidity, temperature, and atmosphere) is critical to the operation of electrospinning, especially for the fabrication of ceramic nanofibers. As would be appreciated by those of skill in the art, these features make the electrospinning process rather expensive as well as resource and time-consuming. The other conventional nanofiber fabrication methods suffer from similar drawbacks and production bottlenecks, which reduce their throughput. In addition, the conventional nanofiber fabrication techniques such as the aforesaid electrospinning process are not suitable for manufacturing metal oxide nanofibers.

Thus, new techniques for manufacturing of nanofibers, including, without limitation, metal oxide nanofibers, are needed to address the growing industrial demands for these materials.

### SUMMARY OF THE INVENTION

The inventive methodology is directed to methods and systems that substantially obviate one or more of the above and other problems associated with conventional techniques for producing nanoparticles and nanofibers.

In accordance with one aspect of the present invention there is provided a method for synthesizing monocrystalline alumina Al₂O₃ nanofibers directly from a melt comprising molten metallic aluminum, the method involving a controlled liquid phase oxidation of the melt. In the inventive method, the nanofibers have a diameter between 3 and 45 nm and length of more than 100 nm.

In one or more embodiments, the synthesis of the monocrystalline alumina Al₂O₃ nanofibers is performed at a temperature of the melt within a range of 660° C. to 1000° C.

In one or more embodiments, the melt further includes at least one of:
a. Vanadium(V) at concentration between 0.000001 and 12 wt. %;
b. Chrome(Cr) at concentration between 0.000001 and 12 wt. %;
c. Manganese (Mn) at concentration between 0.001 and 12 wt. %;
d. Iron (Fe) at concentration between 0.01 and 12 wt. %;
e. Cobalt (Co) at concentration between 0.000001 and 12 wt. %;
f. Nickel (Ni) at concentration between 0.000001 and 12 wt. %;
g. Copper (Cu) at concentration between 0.000001 and 12 wt. %;
h. Zink (Zn) at concentration between 0.000001 and 12 wt. %;
i. Selenium (Se) at concentration between 0.000001 and 12 wt. %;
j. Silicon (Si) at concentration between 0.01 and 12 wt. %;
k. Sulfur (S) at concentration between 0.000001 and 12 wt. %;
l. Tellurium (Te) at concentration between 0.000001 and 12 wt. %;
m. Cerium (Ce) at concentration between 0.000001 and 12 wt. %;
n. Praseodimium (Pr) at concentration between 0.000001 and 12 wt. %;
o. Neodimium (Nd) at concentration between 0.000001 and 12 wt. %;
p. Promethium (Pm) at concentration between 0.000001 and 12 wt. %;
q. Samarium (Sm) at concentration between 0.000001 and 12 wt. %;
r. Europium (Eu) at concentration between 0.000001 and 12 wt. %;
s. Gadolinium (Gd) at concentration between 0.000001 and 12 wt. %;
t. Terbium (Tb) at concentration between 0.000001 and 12 wt. %;
u. Dysprosium (Dy) at concentration between 0.000001 and 12 wt. %;
v. Holmium (Ho) at concentration between 0.000001 and 12 wt. %;
w. Erbium (Er) at concentration between 0.000001 and 12 wt. %;
x. Thulium (Tm) at concentration between 0.000001 and 12 wt. %;
y. Ytterbium (Yb) at concentration between 0.000001 and 12 wt. %; and
z. Lutecium (Lu) at concentration between 0.000001 and 12 wt. %.
   In one or more embodiments, a. through z. summed up represent less than 49 wt. % of the melt, all other elements (except for aluminum) represent less than 0.03 wt. % each, and all other elements (except for aluminum) together comprise less than 1 wt. % of the melt.

In one or more embodiments, the synthesis of the monocrystalline alumina Al₂O₃ nanofibers is performed at oxygen content between 0.001 and 5 wt. %.

In one or more embodiments, the growth of the monocrystalline alumina Al₂O₃ nanofibers takes place on the surface of melt or on the boundary of the melt and another medium.

In one or more embodiments, the inventive method further involves harvesting the grown monocrystalline alumina Al₂O₃ nanofibers from the surface of the melt or from the boundary of the melt and another medium.

In accordance with another aspect of the present invention there is provided a method for synthesizing monocrystalline alumina Al₂O₃ nanofibers. The inventive method involves: obtaining a melt by heating metallic aluminum in a reactor; controlling oxygen content inside the reactor; adding at least one additive to the melt; and performing controlled liquid phase oxidation of the melt by providing additional oxygen into the reactor. In the inventive method, the synthesized monocrystalline alumina Al₂O₃ nanofibers have a diameter between 3 and 45 nm and length of more than 100 nm.

In one or more embodiments, the synthesis of the monocrystalline alumina Al₂O₃ nanofibers is performed at a temperature of the melt within a range of 660° C. to 1000° C.

In one or more embodiments, the at least one additive includes at least one of:
a. Vanadium(V) at concentration between 0.000001 and 12 wt. %;
b. Chrome(Cr) at concentration between 0.000001 and 12 wt. %;
c. Manganese (Mn) at concentration between 0.001 and 12 wt. %;
d. Iron (Fe) at concentration between 0.01 and 12 wt. %;
e. Cobalt (Co) at concentration between 0.000001 and 12 wt. %;
f. Nickel (Ni) at concentration between 0.000001 and 12 wt. %;
g. Copper (Cu) at concentration between 0.000001 and 12 wt. %;
h. Zink (Zn) at concentration between 0.000001 and 12 wt. %;
i. Selenium (Se) at concentration between 0.000001 and 12 wt. %;
j. Silicon (Si) at concentration between 0.01 and 12 wt. %;
k. Sulfur (S) at concentration between 0.000001 and 12 wt. %;
l. Tellurium (Te) at concentration between 0.000001 and 12 wt. %;
m. Cerium (Ce) at concentration between 0.000001 and 12 wt. %;
n. Praseodimium (Pr) at concentration between 0.000001 and 12 wt. %;
o. Neodimium (Nd) at concentration between 0.000001 and 12 wt. %;
p. Promethium (Pm) at concentration between 0.000001 and 12 wt. %;
q. Samarium (Sm) at concentration between 0.000001 and 12 wt. %;
r. Europium (Eu) at concentration between 0.000001 and 12 wt. %;
s. Gadolinium (Gd) at concentration between 0.000001 and 12 wt. %;
t. Terbium (Tb) at concentration between 0.000001 and 12 wt. %;
u. Dysprosium (Dy) at concentration between 0.000001 and 12 wt. %;
v. Holmium (Ho) at concentration between 0.000001 and 12 wt. %;
w. Erbium (Er) at concentration between 0.000001 and 12 wt. %;
x. Thulium (Tm) at concentration between 0.000001 and 12 wt. %;
y. Ytterbium (Yb) at concentration between 0.000001 and 12 wt. %; and
z. Lutecium (Lu) at concentration between 0.000001 and 12 wt. %.
   In one or more embodiments, a. through z. summed up represent less than 49 wt. % of the melt, all other elements (except for aluminum) represent less than 0.03 wt. % each, and all other elements (except for aluminum) together comprise less than 1 wt. % of the melt.

In one or more embodiments, the synthesis of the monocrystalline alumina Al₂O₃ nanofibers is performed at oxygen content between 0.001 and 5 wt. %.

In one or more embodiments, the growth of the monocrystalline alumina Al₂O₃ nanofibers takes place on the surface of melt or on the boundary of the melt and another medium.

In one or more embodiments, the inventive method further involves harvesting the grown monocrystalline alumina Al₂O₃ nanofibers from the surface of the melt or from the boundary of the melt and another medium.

In accordance with yet another aspect of the present invention there is provided a reactor for synthesizing monocrystalline alumina Al₂O₃ nanofibers. The inventive reactor incorporates: a reaction chamber and a heating mechanism for heating metallic aluminum to obtain a melt, the metallic aluminum being heated in the reaction chamber; a valve assembly for controlling oxygen content inside the reactor; and an inlet for adding at least one additive to the melt and providing additional oxygen into the reaction chamber. A controlled liquid phase oxidation of the melt takes place inside the reaction chamber to synthesize monocrystalline alumina Al₂O₃ nanofibers when additional oxygen is provided into the reaction chamber. The synthesized monocrystalline alumina Al₂O₃ nanofibers have a diameter between 3 and 45 nm and length of more than 100 nm.

In one or more embodiments, the reactor further incorporates a sensor assembly for monitoring at least one parameter inside the reaction chamber.

In one or more embodiments, the heating mechanism is an induction based heating mechanism.

In one or more embodiments, the reactor further incorporates a cover closing the reaction chamber adopted for removal of the synthesized monocrystalline alumina Al₂O₃ nanofibers.

In one or more embodiments, the reactor further incorporates a control logic configured to maintain at oxygen content inside the reactor between 0.001 and 5 wt. %.

In one or more embodiments, the reactor further incorporates a stirring mechanism for achieving homogeneity of the melt.

Additional aspects related to the invention will be set forth in part in the description which follows, and in part will be obvious from the description, or may be learned by practice of the invention. Aspects of the invention may be realized and attained by means of the elements and combinations of various elements and aspects particularly pointed out in the following detailed description and the appended claims.

It is to be understood that both the foregoing and the following descriptions are exemplary and explanatory only and are not intended to limit the claimed invention or application thereof in any manner whatsoever.

### BRIEF DESCRIPTION OF THE DRAWINGS

The accompanying drawings, which are incorporated in and constitute a part of this specification exemplify the embodiments of the present invention and, together with the description, serve to explain and illustrate principles of the inventive technique. Specifically:

FIG. 1 illustrates an exemplary embodiment of a reactor for synthesis of aluminum oxide nanofibers.

FIG. 2 illustrates an exemplary embodiment of the inventive method for production of aluminum oxide nanofibers.

### DETAILED DESCRIPTION

In the following detailed description, reference will be made to the accompanying drawing(s), in which identical functional elements are designated with like numerals. The aforementioned accompanying drawings show by way of illustration, and not by way of limitation, specific embodiments and implementations consistent with principles of the present invention. These implementations are described in sufficient detail to enable those skilled in the art to practice the invention and it is to be understood that other implementations may be utilized and that structural changes and/or substitutions of various elements may be made without departing from the scope and spirit of present invention. The following detailed description is, therefore, not to be construed in a limited sense.

The most important characteristics of the nanoparticles fabrication process is the consistency of the produced nanoparticle size, as well as diameter to length ratio, and the throughput of the fabrication process. When compared with other methods, nanoparticle synthesis technology called controlled liquid phase oxidation of aluminum (also know as Kutuzov process) achieves the highest degree of size consistency of produced nanoparticles. Using this method, nanoparticles (nanofibers) with diameters between 3 and 45 nanometers and lengths of more than 100 nanometers may be produced. It should be noted that the length of the produced nanoparticles (nanofibers) is not limited in the aforesaid process and that fibers of any length may be achieved. Moreover, the aforesaid nanofiber synthesis process provides high throughput reaching several kilograms of high quality nanofibers per hour from one equipment unit.

The below description of various embodiments of the invention, primarily deals with nanofibers possessing two linear dimensions of less than 45 nm. Because the nanofibers described herein have circular cross section, the size of the nanofiber will be specified below by reference to its diameter.

In accordance with one or more embodiments of the invention, there is provided a method for synthesizing monocrystalline alumina nanofibers by controlled liquid phase oxidation of aluminum. In one or more embodiments, the method comprises two stages. During the first stage, various additives are introduced into molten metallic aluminum. During the second stage, the alumina nanofibers are synthesized from the resulting melt in the presence of oxygen. In one or more embodiments, the inventive method is performed in a reactor.

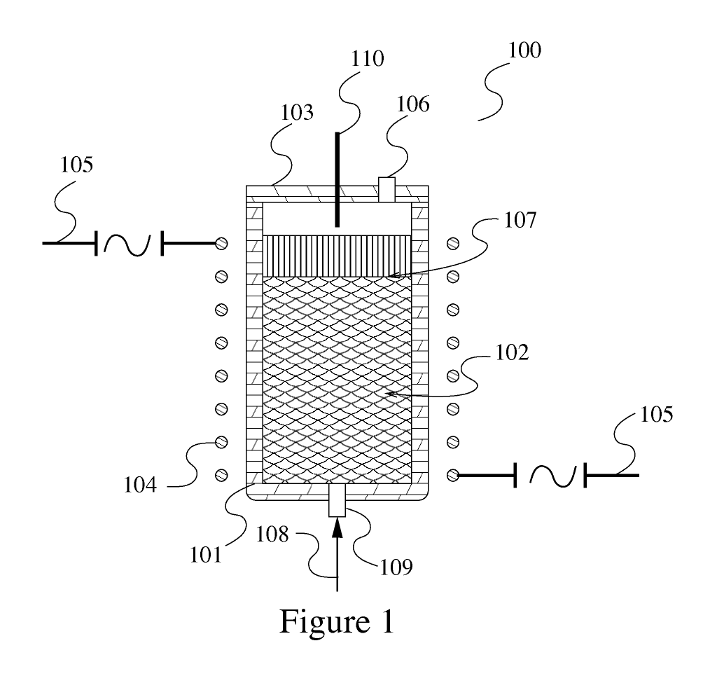

In accordance with one or more embodiments of the invention, the reactor is designed to provide the heating and enable melting of the aluminum. An exemplary embodiment of the reactor 100 is illustrated in FIG. 1. The shown embodiment of the reactor 100 incorporates reactor body 101 enclosing a reaction chamber, which contains the melt 102. The reactor 100 is closed from the top using cover 103, which may incorporate one or more sensor assembly 110 for monitoring various parameters inside the reactor 100, including, without limitation, temperature, pressure and oxygen content. The reactor cover 103 may also incorporate one or more valve assemblies 106 for controlling the atmosphere inside the reactor. In addition, an inlet 109 may be provided in the bottom part of the reactor 100 for injecting various additives and oxygen into the reactor 100, see numeral 108. In one or more embodiments, the content of the reactor may be heated using a suitable induction heating mechanism, which may incorporate induction coil 104 electrically connected to an electric current source 105. The zone of synthesis of aluminum oxide nanofibers is marked in Figure with numeral 107. The oxygen content inside the reactor 100 may be automatically monitored and/or altered using control logic.

In one or more embodiments, the reactor is designed to maintain a sustained temperature of between 660° C. and 1,000° C. When the additives described below are introduced into the molten aluminum, it is desirable to provide steady and uniform the stirring of the melt. To this end, the aforesaid reactor may be provided with a stirring mechanism (not shown in FIG. 1). The construction of the reactor should also provide control over gas composition of the atmosphere during both the introduction of the additives and during the synthesis of the nanofibers. In one or more embodiments, the oxygen content of the atmosphere should be 0.00001 wt. % (weight percent) to 99.9 wt. % depending on the stage of the synthesis process.

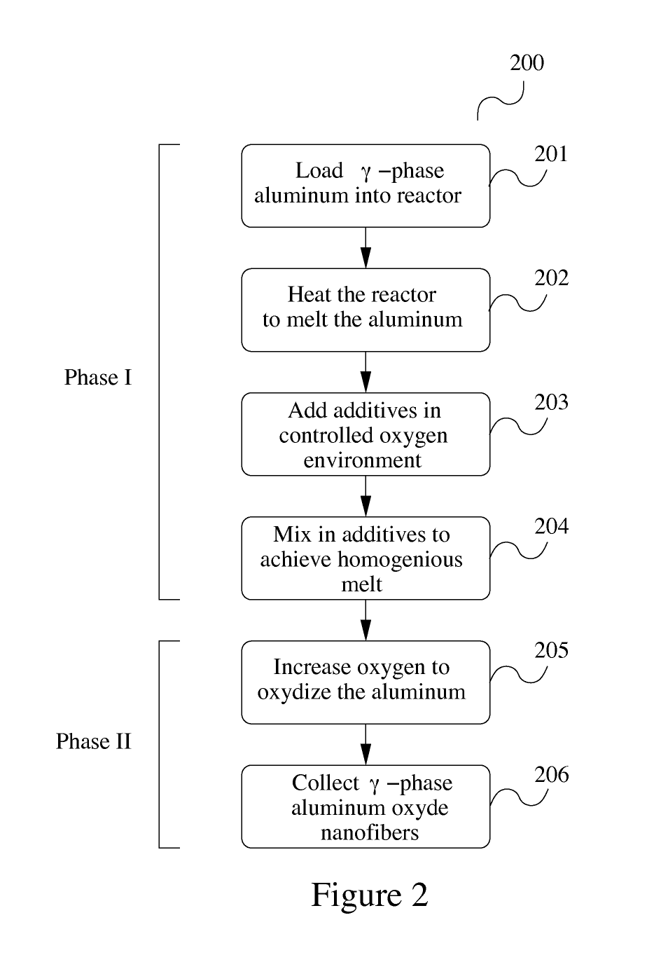

FIG. 2 illustrates an exemplary embodiment of the inventive method 200 for production of aluminum oxide nanofibers. In accordance with one or more embodiments of the invention, during the first, additive introduction phase (Phase I in FIG. 2) of the inventive process 200, the oxygen content of the atmosphere is kept to the minimal oxygen concentration. On the other hand, during the second, synthesis stage (Phase II in FIG. 2), the oxygen content should be higher, depending on the temperature and the required speed of the nanofiber synthesis process.

In accordance with one or more embodiments of the invention, the heating of the melt is performed using induction heating or electrical resistance heating (ERH, also known as electrical resistive heating) methods, which are well known to persons of ordinary skill in the art. To this end, the reactor may incorporate an appropriate heater. However, the present invention is not limited only to the aforesaid induction heating or electrical resistance heating methods and any other suitable heating method could be utilized for heating, melting and maintaining the required temperature of the material. It should be noted that the heater should preferably provide even heating of the entire volume of the material in the reactor. In addition, in one or more embodiment, the reactor incorporates means for controlling the content of the atmosphere inside the reactor. Construction and methods of application of such means are well known to persons of ordinary skill in the art.

In accordance with one or more embodiments of the invention, in order to synthesize alumina nanofibers, metallic aluminum having purity of 99.7% is first loaded into the reactor 100 in step 201 and melted in the reactor n step 202, see FIG. 2. It should be noted that it is also possible to use other grades of aluminum, as long as the chemical composition of the material described below is achieved. In accordance with one or more embodiments of the invention, the melt is subsequently heated to 900° C., and additives are introduced into the melt to achieve certain predetermined concentrations.

In accordance with one or more embodiments of the invention, the following additives are introduced into the heated melt in step 203 to achieve an additive concentration in the range indicated next to the respective additive:
a. Vanadium(V) at concentration between 0.000001 and 12 wt. %;
b. Chrome(Cr) at concentration between 0.000001 and 12 wt. %;
c. Manganese (Mn) at concentration between 0.001 and 12 wt. %;
d. Iron (Fe) at concentration between 0.01 and 12 wt. %;
e. Cobalt (Co) at concentration between 0.000001 and 12 wt. %;
f. Nickel (Ni) at concentration between 0.000001 and 12 wt. %;
g. Copper (Cu) at concentration between 0.000001 and 12 wt. %;
h. Zink (Zn) at concentration between 0.000001 and 12 wt. %;
i. Selenium (Se) at concentration between 0.000001 and 12 wt. %;
j. Silicon (Si) at concentration between 0.01 and 12 wt. %;
k. Sulfur (S) at concentration between 0.000001 and 12 wt. %;
l. Tellurium (Te) at concentration between 0.000001 and 12 wt. %;
m. Cerium (Ce) at concentration between 0.000001 and 12 wt. %;
n. Praseodimium (Pr) at concentration between 0.000001 and 12 wt. %;
o. Neodimium (Nd) at concentration between 0.000001 and 12 wt. %;
p. Promethium (Pm) at concentration between 0.000001 and 12 wt. %;
q. Samarium (Sm) at concentration between 0.000001 and 12 wt. %;
r. Europium (Eu) at concentration between 0.000001 and 12 wt. %;
s. Gadolinium (Gd) at concentration between 0.000001 and 12 wt. %;
t. Terbium (Tb) at concentration between 0.000001 and 12 wt. %;
u. Dysprosium (Dy) at concentration between 0.000001 and 12 wt. %;
v. Holmium (Ho) at concentration between 0.000001 and 12 wt. %;
w. Erbium (Er) at concentration between 0.000001 and 12 wt. %;
x. Thulium (Tm) at concentration between 0.000001 and 12 wt. %;
y. Ytterbium (Yb) at concentration between 0.000001 and 12 wt. %; and
z. Lutecium (Lu) at concentration between 0.000001 and 12 wt. %.

In one or more embodiments, a. through z. above summed up represent less than 49 wt. % of the molten metallic aluminum, all other elements (except for aluminum) represent less than 0.03 wt. % each, and all other elements (except for aluminum) together comprise less than 1 wt. % of the molten metallic aluminum.

In accordance with one or more embodiments of the invention, the aforesaid additives are introduced into the melt not in their pure form, but as part of compositions and/or alloys. This may facilitate the dissolution of the respective additives in the melt and result in a higher degree of homogeneity of the melt.

In one embodiment of the inventive technique, one or more of the aforesaid additives are introduced into the melt in a solid powder form. In an alternative embodiment, the additives may be introduced in a pre-melted form. To facilitate attaining the proper homogeneity of the resulting melt, in one or more embodiments, the stirring mechanism may be used in the reactor 100 to perform mixing in of the additives in step 204, see FIG. 2.

In accordance with one or more embodiments of the invention, once suitably homogeneous melt is obtained, oxygen is introduced into the melt, see step 205. In one or more embodiments, oxygen is introduced through melt's surface by means of diffusion. In another embodiment, oxygen is injected into the melt using an injector. Finally, in an alternative embodiment, oxygen is introduced into the melt through introducing a composition or compositions of oxygen with one or more of the following chemical elements: Vanadium (V), Chrome (Cr), Manganese (Mn), Iron (Fe), Cobalt (Co), Nickel (Ni), Cuprum (Cu) , Zink (Zn), Selenium (Se), Silicon (Si), Sulfur (S), Tellurium (Te), Cerium (Ce), Praseodimium (Pr), Neodimium (Nd), Promethium (Pm), Samarium (Sm), Europium (Eu), Gadolinium (Gd), Terbium (Tb), Dysprosium (Dy), Holmium (Ho), Erbium (Er), Thulium (Tm), Ytterbium (Yb), Lutecium (Lu).

In accordance with one or more embodiments of the invention, oxygen is introduced up to a concentration of 0.001 to 5 wt. %. Once oxygen is introduced and reaches the indicated concentration, the synthesis of nanofibers takes place either on the surface of the melt or on a boundary between the molten aluminum and another medium. In one or more embodiments, the grown monocrystalline alumina Al₂O₃ nanofibers are harvested from the surface of the molten metallic aluminum or from the boundary of the molten metallic aluminum and another medium. In accordance with one or more embodiments of the invention, the synthesis of the monocrystalline alumina Al₂O₃ nanofibers is performed within temperature range of the molten metallic aluminum from 660° C. to 1000° C. Finally, the aluminum nanofibers are collected at step 206. In one or more embodiments, the aluminum nanofibers are synthesized in gamma phase. In various alternative embodiments, the aluminum nanofibers may be synthesized in Xi phase or other phases, depending on the specific parameters of the synthesis process.

In accordance with one or more embodiments of the invention, it order to insure continuous nanofiber synthesis process, it is desirable to provide a steady supply of oxygen to the reactor to maintain oxygen concentration within desired limits. In addition, the chemical composition of the melt and the temperature should also be appropriately maintained within proper limits during the synthesis process.

As the alumina nanofibers are formed on the surface of the melt during the synthesis process, they can be harvested from the melt's surface. The diameter of the produced nanofibers can be controlled through the parameters of the synthesis process, such as temperature and chemical composition of the melt. On the other hand, the length of the produced nanofibers is determined by synthesis time. In one or more embodiments, the nanofiber synthesis speed may vary from 0.01 mm/hour to 100 mm/hour.

It should be noted that the described method may also be utilized to synthesize polycrystalline alumina nanofibers by changing the synthesis conditions during the synthesis process and/or by applying an external action on the surface of the molten aluminum.

Moreover, other implementations of the invention will be apparent to those skilled in the art from consideration of the specification and practice of the invention disclosed herein. Various aspects and/or components of the described embodiments may be used singly or in any combination in the process for nanofiber synthesis. It is intended that the specification and examples be considered as exemplary only, with a true scope and spirit of the invention being indicated by the following claims.

What is claimed is:

1. A method for synthesizing monocrystalline alumina Al₂O₃ nanofibers directly from a melt comprising molten metallic aluminum, the method comprising a controlled liquid phase oxidation of the melt, wherein the synthesized monocrystalline alumina Al₂O₃ nanofibers have a diameter between 3 and 45 nm and length of more than 100 nm.

2. The method of claim 1, wherein the synthesis of the monocrystalline alumina Al₂O₃ nanofibers is performed at a temperature of the melt within a range of 660° C. to 1000° C.

3. The method of claim 1, wherein the melt further comprises at least one of:
a. Vanadium(V) at concentration between 0.000001 and 12 wt. %;
b. Chrome(Cr) at concentration between 0.000001 and 12 wt. %;
c. Manganese (Mn) at concentration between 0.001 and 12 wt. %;
d. Iron (Fe) at concentration between 0.01 and 12 wt. %;
e. Cobalt (Co) at concentration between 0.000001 and 12 wt. %;
f. Nickel (Ni) at concentration between 0.000001 and 12 wt. %;
g. Copper (Cu) at concentration between 0.000001 and 12 wt. %;
h. Zink (Zn) at concentration between 0.000001 and 12 wt. %;
i. Selenium (Se) at concentration between 0.000001 and 12 wt. %;
j. Silicon (Si) at concentration between 0.01 and 12 wt. %;
k. Sulfur (S) at concentration between 0.000001 and 12 wt. %;
l. Tellurium (Te) at concentration between 0.000001 and 12 wt. %;
m. Cerium (Ce) at concentration between 0.000001 and 12 wt. %;
n. Praseodimium (Pr) at concentration between 0.000001 and 12 wt. %;
o. Neodimium (Nd) at concentration between 0.000001 and 12 wt. %;
p. Promethium (Pm) at concentration between 0.000001 and 12 wt. %;
q. Samarium (Sm) at concentration between 0.000001 and 12 wt. %;
r. Europium (Eu) at concentration between 0.000001 and 12 wt. %;
s. Gadolinium (Gd) at concentration between 0.000001 and 12 wt. %;
t. Terbium (Tb) at concentration between 0.000001 and 12 wt. %;
u. Dysprosium (Dy) at concentration between 0.000001 and 12 wt. %;
v. Holmium (Ho) at concentration between 0.000001 and 12 wt. %;
w. Erbium (Er) at concentration between 0.000001 and 12 wt. %;
x. Thulium (Tm) at concentration between 0.000001 and 12 wt. %;
y. Ytterbium (Yb) at concentration between 0.000001 and 12 wt. %; and
z. Lutecium (Lu) at concentration between 0.000001 and 12 wt. %.
wherein a. through z. summed up represent less than 49 wt. % of the melt and wherein all other elements (except for metallic aluminum) represent less than 0.03 wt. % each, and wherein all other elements (except for metallic aluminum) together comprise less than 1 wt. % of the melt.

4. The method of claim 1, wherein the synthesis of the monocrystalline alumina Al₂O₃ nanofibers is performed at oxygen content between 0.001 and 5 wt. %.

5. The method of claim 1, wherein the growth of the monocrystalline alumina Al₂O₃ nanofibers takes place on the surface of the melt.

6. The method of claim 1, wherein the growth of the monocrystalline alumina Al₂O₃ nanofibers takes place on the boundary of the melt and another medium.

7. The method of claim 1, further comprising harvesting the grown monocrystalline alumina Al₂O₃ nanofibers from the surface of the melt or from the boundary of the melt and another medium.

8. A method for synthesizing monocrystalline alumina Al₂O₃ nanofibers, the method comprising:
a. obtaining a melt by heating metallic aluminum in a reactor;
b. controlling oxygen content inside the reactor;
c. adding at least one additive to the melt; and
d. performing controlled liquid phase oxidation of the melt by providing additional oxygen into the reactor, wherein the synthesized monocrystalline alumina Al₂O₃ nanofibers have a diameter between 3 and 45 nm and length of more than 100 nm.

9. The method of claim 8, wherein the synthesis of the monocrystalline alumina Al₂O₃ nanofibers is performed at a temperature of the melt within a range of 660° C. to 1000° C.

10. The method of claim 8, wherein the at least one additive comprises at least one of:
a. Vanadium(V) at concentration between 0.000001 and 12 wt. %;
b. Chrome(Cr) at concentration between 0.000001 and 12 wt. %;
c. Manganese (Mn) at concentration between 0.001 and 12 wt. %;
d. Iron (Fe) at concentration between 0.01 and 12 wt. %;
e. Cobalt (Co) at concentration between 0.000001 and 12 wt. %;
f. Nickel (Ni) at concentration between 0.000001 and 12 wt. %;
g. Copper (Cu) at concentration between 0.000001 and 12 wt. %;
h. Zink (Zn) at concentration between 0.000001 and 12 wt. %;
i. Selenium (Se) at concentration between 0.000001 and 12 wt. %;
j. Silicon (Si) at concentration between 0.01 and 12 wt. %;
k. Sulfur (S) at concentration between 0.000001 and 12 wt. %;
l. Tellurium (Te) at concentration between 0.000001 and 12 wt. %;
m. Cerium (Ce) at concentration between 0.000001 and 12 wt. %;
n. Praseodimium (Pr) at concentration between 0.000001 and 12 wt. %;
o. Neodimium (Nd) at concentration between 0.000001 and 12 wt. %;
p. Promethium (Pm) at concentration between 0.000001 and 12 wt. %;
q. Samarium (Sm) at concentration between 0.000001 and 12 wt. %;
r. Europium (Eu) at concentration between 0.000001 and 12 wt. %;
s. Gadolinium (Gd) at concentration between 0.000001 and 12 wt. %;
t. Terbium (Tb) at concentration between 0.000001 and 12 wt. %;
u. Dysprosium (Dy) at concentration between 0.000001 and 12 wt. %;
v. Holmium (Ho) at concentration between 0.000001 and 12 wt. %;
w. Erbium (Er) at concentration between 0.000001 and 12 wt. %;
x. Thulium (Tm) at concentration between 0.000001 and 12 wt. %;
y. Ytterbium (Yb) at concentration between 0.000001 and 12 wt. %; and
z. Lutecium (Lu) at concentration between 0.000001 and 12 wt. %.
wherein a. through z. summed up represent less than 49 wt. % of the melt and wherein all other elements (except for metallic aluminum) represent less than 0.03 wt. % each, and wherein all other elements (except for metallic aluminum) together comprise less than 1 wt. % of the melt.

11. The method of claim 8, wherein the synthesis of the monocrystalline alumina Al₂O₃ nanofibers is performed at oxygen content between 0.001 and 5 wt. %.

12. The method of claim 8, wherein the growth of the monocrystalline alumina Al₂O₃ nanofibers takes place on the surface of the melt.

13. The method of claim 8, wherein the growth of the monocrystalline alumina Al₂O₃ nanofibers takes place on the boundary of the melt and another medium.

14. The method of claim 8, further comprising harvesting the grown monocrystalline alumina Al₂O₃ nanofibers from the surface of the melt or from the boundary of the melt and another medium.

15. A reactor for synthesizing monocrystalline alumina Al₂O₃ nanofibers, the reactor comprising:
a. a reaction chamber and a heating mechanism for heating metallic aluminum to obtain a melt, the metallic aluminum being heated in the reaction chamber;
b. a valve assembly for controlling oxygen content inside the reactor; and
c. an inlet for adding at least one additive to the melt and providing additional oxygen into the reaction chamber, wherein controlled liquid phase oxidation of the melt takes place inside the reaction chamber to synthesize monocrystalline alumina Al₂O₃ nanofibers when additional oxygen is provided into the reaction chamber and wherein the synthesized monocrystalline alumina Al₂O₃ nanofibers have a diameter between 3 and 45 nm and length of more than 100 nm.

16. The reactor of claim 15, further comprising a sensor assembly for monitoring at least one parameter inside the reaction chamber.

17. The reactor of claim 15, wherein the heating mechanism is an induction based heating mechanism.

18. The reactor of claim 15, further comprising a cover closing the reaction chamber and adopted for removal of the synthesized monocrystalline alumina Al₂O₃ nanofibers.

19. The reactor of claim 15, further comprising control logic configured to maintain at oxygen content inside the reactor between 0.001 and 5 wt. %.

20. The reactor of claim 15, further comprising a stirring mechanism for achieving homogeneity of the melt.
